(19) United States
(12) Patent Application Publication
(10) Pub. No.: US 2017/0154803 A1
(43) Pub. Date: Jun. 1, 2017

(54) NON-CONTACT WAFER TRANSPORT DEVICE

(71) Applicants: Yi-Cheng WANG, Hsinchu (TW); WET Technology Co., Ltd., Hsinchu (TW)

(72) Inventors: Yi-Cheng WANG, Hsinchu (TW); Pech-Chin WANG, Hsinchu (TW); Han-Ming HUANG, Hsinchu (TW)

(21) Appl. No.: 14/955,717

(22) Filed: Dec. 1, 2015

(51) Int. Cl. H01L 21/683; B65G 47/91

(52) U.S. Cl. CPC H01L 21/6838; B65G 47/91

(57) ABSTRACT

A non-contact wafer transport device for transporting a wafer to be transported includes a base, a moving arm, a tube disposed in the moving arm and a negative pressure device. The moving arm is pivotally connected to the base, moves relatively to the base, and includes an operating end away from the base. The tube includes a channel that accommodates a fluid, and a suction port that is in communication with the channel and formed at the suction port. The negative pressure device, connected to the channel, generates a negative pressure upon the fluid in the channel to cause the suction port to form a suction force. The suction force acts on the wafer to be transported and causes the wafer to be transported to be kept at a distance from the operating end. Thus, without contacting the wafer, the wafer to be transported can be transported.

### FIELD OF THE INVENTION

The present invention relates to a wafer transport device, and particularly to a non-contact wafer contact device.

### BACKGROUND OF THE INVENTION

The fabrication process of integrated circuits involve tens to even hundreds of steps. Along with the development trend of electronic information products aiming at being light and compact, if the fabrication process of integrated circuits is still performed using conventional manual operations as in the old days, errors may be caused to lead to a lowered yield rate. Further, such fabrication process that is getting more and more complicated consumes tremendous amounts of human power. Thus, current foundry houses utilize mechanical arms in the replacement of manual power to transport wafers.

For example, the U.S. Pat. No. 6,918,735, “Holding Device for Wafers”, discloses a holding device for wafers. The holding device includes a holding arm, two grippers oppositely mounted on the holding arm, and a drive device electrically connected to the two grippers. The drive device controls the opening and closing of the two grippers, which are then enabled to hold a subsection of the wafer circumference for movement.

However, when the two grippers hold the wafer, the wafer is likely bent or damaged due to uneven forces applied. Further, the two grippers block a part of the surface of the wafer and may thus hinder the subsequent fabrication process. In addition, after operations for a period of time, positions at which the two grippers hold and place the wafer may be deviated to scratch the wafer. Therefore, it is an essential task to provide a solution for solving issues of wafer damage caused by the holding device and the hindrance from the subsequent fabrication process due to the blocking of the holding device.

### SUMMARY OF THE INVENTION

The primary object of the present invention is to provide a solution for solving issues of wafer damage caused by a conventional holding device and the hindrance from the subsequent fabrication process due to the blocking of the holding device.

To achieve the object, the present invention provides a non-contact wafer transport device for transporting a wafer to be transported. The non-contact wafer transport device includes a base, a moving arm, a tube and a negative pressure device. The moving arm is pivotally connected to the base, moves relatively to the base, and includes an operating end away from the base. The tube is disposed in the moving arm, and includes a channel that accommodates a fluid and a suction port that is in communication with the channel and formed at the operating end. The negative device, connected to the channel, generates a negative pressure upon the fluid in the channel to cause the operating end to generate a suction force. The suction force acts on the wafer to be transported, and causes the wafer to be transported to be kept at an operating distance from the suction port.

In conclusion, the negative pressure device of the present invention generates a negative pressure upon the fluid in the channel to cause the suction port to generate a suction force. The suction force draws and engages the wafer to be transported, and causes the wafer to be kept at a distance from the suction port. Thus, without coming into contact with the wafer to be transported, the wafer transport device of the present invention is capable of transporting the wafer to be transported to different positions as well as solving issues of wafer damage caused by a conventional holding device and the hindrance from the subsequent fabrication process due to the blocking of the holding device.

### BRIEF DESCRIPTION OF THE DRAWINGS

FIG. 1 is a section view according to a first embodiment of the present invention;

FIG. 2A to FIG. 2C are schematic diagrams of operation steps of a process according to the first embodiment of the present invention;

FIG. 3 is a section view according to a third embodiment of the present invention; and

FIG. 4 is a section view according to a third embodiment of the present invention.

### DETAILED DESCRIPTION OF THE PREFERRED EMBODIMENTS

Details and technical contents of the present invention are given with the accompanying drawings below.

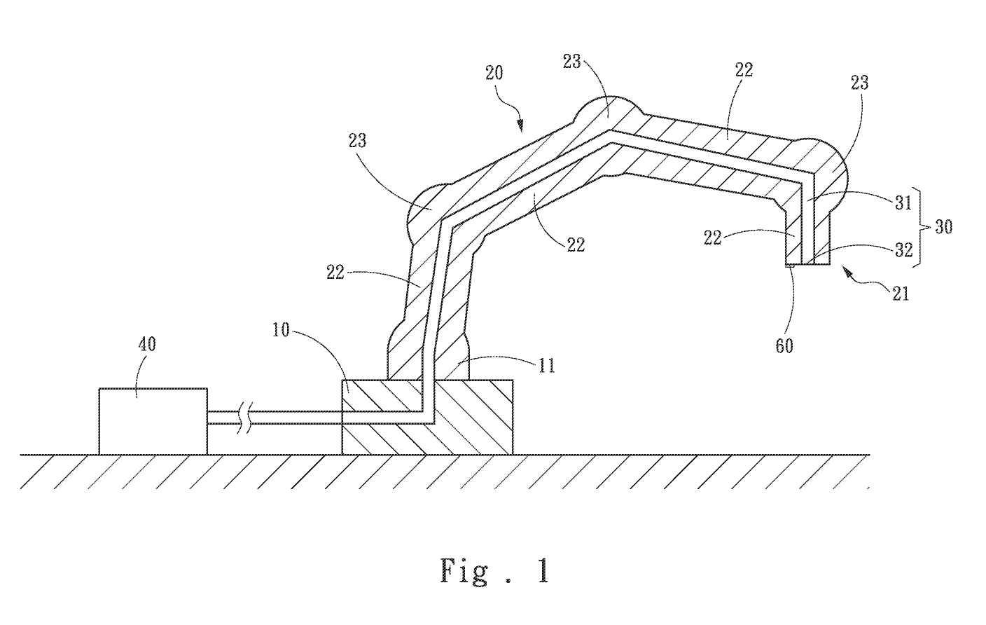

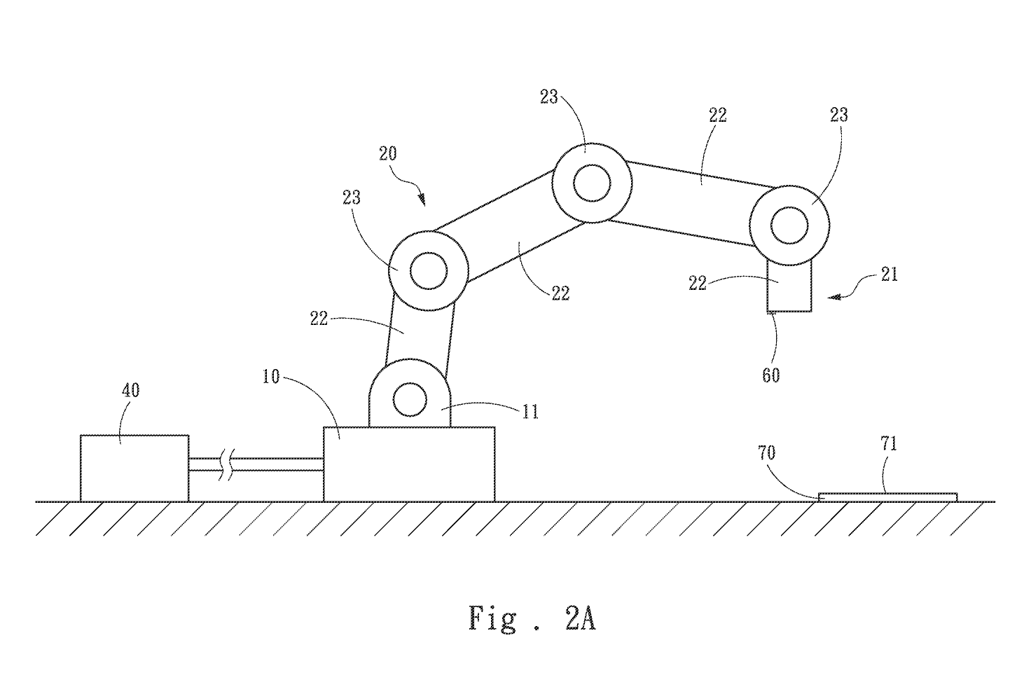

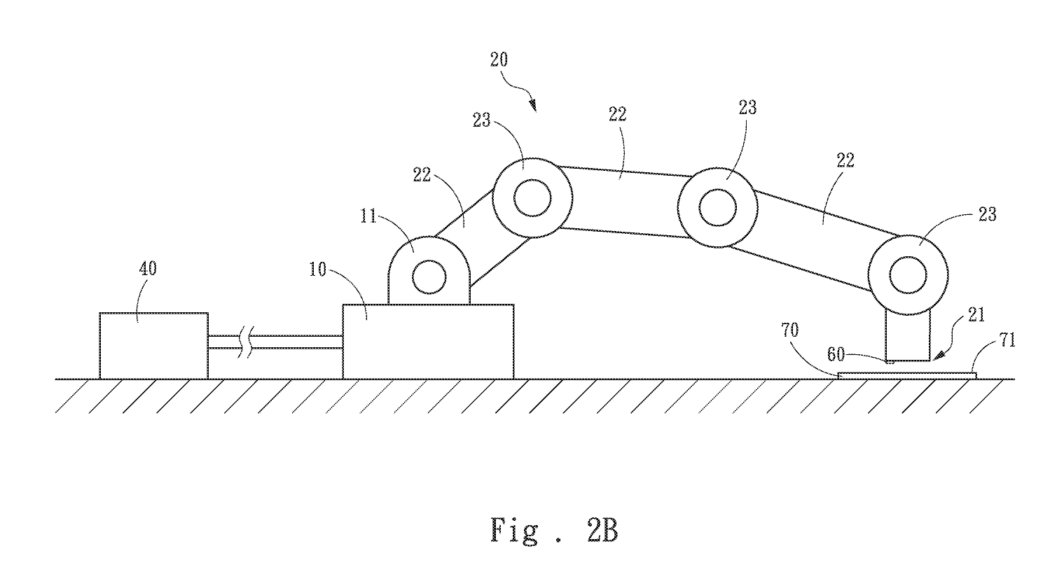

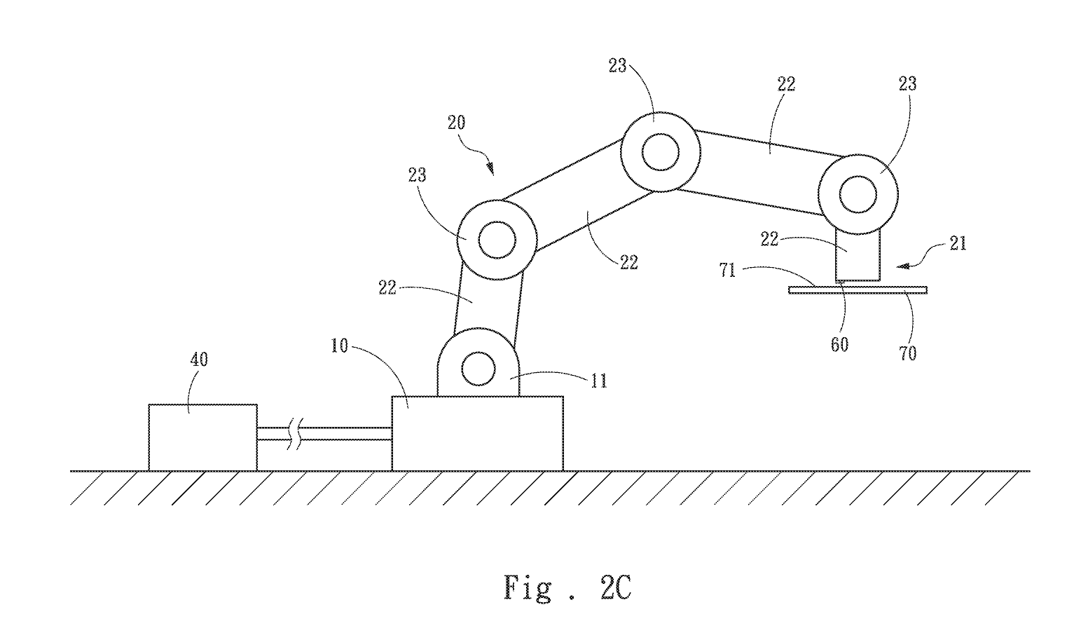

FIG. 1 and FIG. 2A to FIG. 2C are a section view and schematic diagrams of operation steps of a process according to a first embodiment of the present invention. The present invention provides a non-contact wafer transport device for transporting a wafer 70 to be transported. The non-contact wafer transport device includes a base 10, a moving arm 20, a tube 30 and a negative pressure device 40. The moving arm 20 is pivotally connected to the base 10, moves relatively to the base 10, and includes an operating end 21 away from the base 10. The tube 30, disposed in the moving arm 20, includes a channel 31 that accommodates a fluid and a suction port 32 that is in communication with the channel 31 and formed at the operating end 21. In the embodiment, the base 10 further includes a pivotal member 11, through which the moving arm 20 is pivotally connected to the base 10. Further, the tube 30 extends to the base 10 and then connects to the negative pressure device 40. However, instead of also extending to the base 10, the tube 30 may be disposed only at the moving arm 20.

In the embodiment, the moving arm 20 further includes a plurality of sub-arms 22 and a plurality of rotation units 23 respectively disposed between the sub-arms 22. Through operations of the rotation units 23, relative positions of the sub-arms 22 are controlled to allow the moving arm 20 to operate within a predetermined distance. Further, a sensing member 60 is disposed at the operating end 21 to detect the distance between the wafer 70 to be transported and the operating end 21.

Referring to FIG. 2A to FIG. 2C, during operations, the rotation units 23 operate to cause the operating end 21 of the moving arm 20 to approach the wafer 70 to be transported. The negative pressure device 40 then operates to generate a negative pressure upon the fluid in the channel 31 to cause the suction port 32 to generate a suction force. The suction force acts on the wafer 70 to be transported and draws and engages the wafer 70 to be transported. Alternatively, using a viscous force between the fluid and the operating end 21, given that the fluid stays present, the wafer 70 to be transported stays constantly drawn and engaged, and can be kept at an operating distance from the operating end 21. When the sensing member 60 detects that the wafer 70 to be transported is kept at the operating distance from the operating end 21, the moving arm 20 transports the wafer 70 to be transported to proceed to a next step in the fabrication process. Therefore, without coming into contact with the wafer 70 to be transported, the wafer 70 to be transported can be transported, thereby preventing issues of wafer damage caused by a conventional holding device holding the wafer 70 to be transported and the hindrance from the subsequent fabrication process due to the conventional holding device blocking an upper surface 71 of the wafer 70 to be transported.

In the present invention, the fluid may be a liquid or a gas, and the liquid may be a liquid having a cleaning or another function. Thus, while the wafer 70 to be transported is being transported, pre-processing of the fabrication process can be performed to reduce the time of the fabrication process. It should be noted that, when the fluid is a liquid, the liquid first forms a liquid layer on the upper surface 71 of the wafer 70 to be transported, and the wafer 70 to be transported is then drawn and engaged by the suction force generated at the suction port 32.

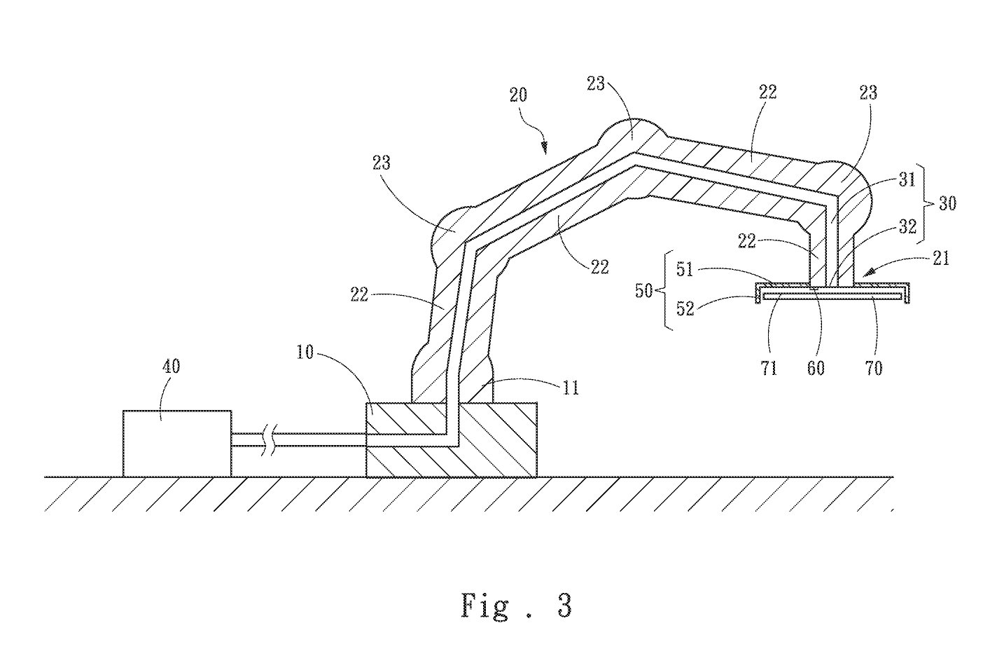

FIG. 3 shows a section view according to a second embodiment of the present invention. Referring to FIG. 3, different from the first embodiment, the non-contact wafer transport device of the second embodiment further includes an auxiliary fixing member 50. The auxiliary fixing member 50 is mounted on the operating end 21, and includes an upper cover 51 that extends outwards from the operating end 21 and covers the upper surface 71 of the wafer 70 to be transported, and a stopping member 52 that extends vertically from a periphery of the upper cover 51. To adapt to the shape of the wafer 70 to be transported, the upper cover 51 may be a round disc in shape. During the transportation process, the wafer 70 to be transported may cause the wafer 70 to be transported to move horizontally due to a faster moving speed of the moving arm 20 or other reasons. However, the suction port 32 may fail to engage the wafer 70 to be transported due to the horizontal movement of the wafer 70 to be transported, such that the wafer 70 to be transported may become disengaged and damaged. Thus, the stopping member 52 limits the horizontal movement of the wafer 70 to be transported, so as to prevent the wafer 70 to be transported from becoming disengaged and damaged, hence preventing issues of increased production costs.

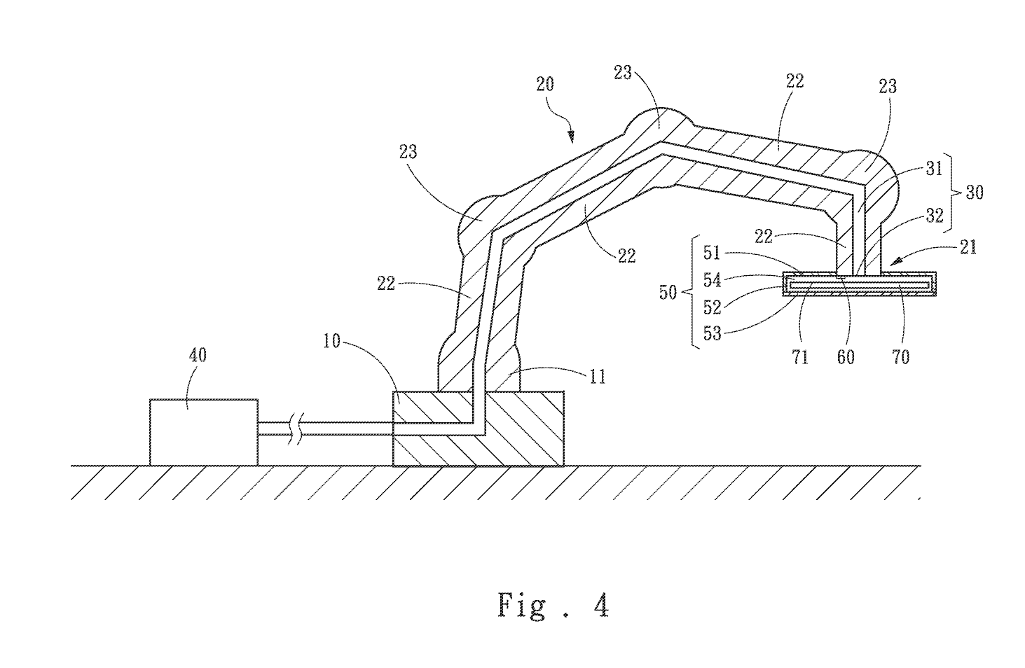

FIG. 4 shows a section view according to a third embodiment of the present invention. Referring to FIG. 4, different from the second embodiment, the auxiliary fixing member 50 in the third embodiment further includes a lower cover 53. The lower cover 53, provided correspondingly to the upper cover 51, is disposed at one side of the stopping member 52 away from the upper cover 51. In the embodiment, the lower cover 53 is connected to the stopping member 52 via a rotation member (not shown) for opening and closing movements to form a cavity 54. During operations, the lower cover 53 first opens, such that the suction port 32 draws and engages the wafer 70 to be transported and is kept at the operating distance from the wafer 70 to be transported. The lower cover 53 then closes. Thus, pre-processing of the fabrication process may be performed in advance while the wafer 70 to be transported is in the cavity. Further, when the wafer 70 to be transported accidentally becomes disengaged, the wafer 70 to be transported falls on the lower cover 53 at a closer position, hence reducing damages caused compared to falling onto the ground or other objects.

In conclusion, in the present invention, the negative pressure device generates a negative pressure upon the fluid in the channel to cause the suction port to generate a suction force. The suction force draws and engages the wafer to be transported, and causes the wafer to be kept at a distance from the suction port. Thus, without coming into contact with the wafer to be transported, the wafer transport device of the present invention is capable of transporting the wafer to be transported to different positions as well as solving issues of wafer damage caused by a conventional holding device and the hindrance from the subsequent fabrication process due to the holding device blocking the upper surface of the wafer to be transported. Further, the fluid may be a liquid having a cleaning or another function, and may perform pre-processing of the fabrication process during a transportation process to reduce the operating time of the fabrication process. Further, using the stopping member, the horizontal movement of the wafer to be transported during the transportation process can be limited to prevent an issue of disengaging and falling due to the suction port being incapable of drawing and engaging the wafer to be transported. Moreover, with the cavity of the auxiliary fixing member, pre-processing of the fabrication process may be performed in advance while the wafer to be transported is in the cavity. If the wafer to be transported is accidentally fallen off, the wafer to be transported falls onto the lower cover at a closer position, thereby reducing damages caused compared to falling onto the ground or other objects.

What is claimed is:

1. A non-contact wafer transport device, for transporting a wafer to be transported, comprising:
a base;
a moving arm, pivotally connected to the base, moving relatively to the base, comprising an operating end away from the base;
a tube, disposed in the moving arm, comprising a channel that accommodates a fluid and a suction port that is in communication with the channel and formed at the operating end; and
a negative pressure device, connected to the channel;
wherein, the negative pressure device generates a negative pressure upon the fluid in the channel to generate a suction force, the suction force acts on the wafer to be transported and causes the wafer to be transported to be kept at an operating distance from the operating end.

2. The non-contact wafer transport device of claim 1, further comprising:
an auxiliary fixing member, mounted on the operating end, comprising an upper cover that extends outwards from the operating end and covers the wafer to be transported, and a stopping member that extends vertically from a periphery of the upper cover and limits a horizontal movement of the wafer to be transported.

3. The non-contact wafer transport device of claim 2, wherein the auxiliary fixing member further comprise:
a lower cover, corresponding to the upper cover, disposed at one side of the stopping member away from the upper cover.

4. The non-contact wafer transport device of claim 2, wherein the upper cover is a round disc in shape.

5. The non-contact wafer transport device of claim 1, wherein the fluid is a gas or a liquid.

6. The non-contact wafer transport device of claim 1, further comprising a sensing member disposed at the operating end.

7. The non-contact wafer transport device of claim 1, wherein the moving arm further comprises a plurality of sub-arms and a plurality of rotation units respectively disposed between the sub-arms.
